(19) United States
(12) Patent Application Publication
(10) Pub. No.: US 2013/0084526 A1
(43) Pub. Date: Apr. 4, 2013

(54) PHOTO-RESIST AND METHOD OF PHOTOLITHOGRAPHY

(71) Applicants: Qiang Wu, Beijing (CN); Yiming Gu, Beijing (CN)

(72) Inventors: Qiang Wu, Beijing (CN); Yiming Gu, Beijing (CN)

(73) Assignee: Semiconductor Manufacturing International (Beijing) Corporaiton, Beijing (CN)

(21) Appl. No.: 13/405,235

(22) Filed: Feb. 25, 2012

(30) Foreign Application Priority Data
Sep. 29, 2011 (CN) 201110295647.8

(51) Int. Cl. G03F 7/20; G03F 7/027; G03F 7/004

(52) U.S. Cl. 430/281.1; 430/270.1; 430/325

(57) ABSTRACT

A photo-resist and a method for performing photolithography using the photo-resist are described. The photo-resist comprises a matrix resin, a first component and a second component. The first component is configured to produce a chemical amplification action and generates a first chemical substance when exposed to a light of a first wavelength band. The first chemical substance will react with the matrix resin to form a latent image. The second component is configured to generate a second chemical substance when exposed to a light of a second wavelength band. The second chemical substance reacts with the first chemical substance to reduce a mass concentration of the first chemical substance.

### CROSS-REFERENCES TO RELATED APPLICATIONS

This application claims priority to Chinese Patent Application No. 201110295647.8, filed on Sep. 29, 2011 and entitled “Method of Forming Gate Pattern and Semiconductor Device”, which is incorporated herein by reference in its entirety.

This patent application is related to the following co-pending, commonly assigned patent applications, the disclosure of which are incorporated herein by reference in their entirety:
1. “Photo-Resist and Method of Photolithography” by Qiang Wu and Yao Xu, Attorney Docket No. 87720-030500US-826645, filed concurrently herewith.
2. “Photolithographic Apparatus” by Qiang Wu and Yiming Gu, Attorney Docket No. 87720-030800US-826765, filed concurrently herewith.

### BACKGROUND OF THE INVENTION

1. Field of the Invention

The present invention relates generally to a photo-resist and a method of photolithography using this photo-resist, and more specifically, to a photo-resist utilizing a chemical amplification action and a method of photolithography using such a photo-resist.

2. Description of the Related Art

With the rapid development of the microelectronic industry, critical dimensions of a semiconductor device continue to shrink. The shrinkage of the critical dimensions of a device depends on exposure tools. On the other hand, the shrinkage is closely related to the selection of a photo-resist. Thus, the selection and application of a photo-resist corresponding to photolithography also become an important research content for photolithographic processes.

The advancement of photolithography promotes the steady improvement in performances of a photo-resist. The photo-resist using a chemical amplification action has many advantages such as high sensitivity and strong ability to withstand dry corrosion, which facilitate subsequent processing steps of a semiconductor device. A chemically amplified photo-resist has thus a broader application prospect in the semiconductor manufacturing field and gradually gains attention in the photolithographic field. It is believed that the chemically amplified photo-resist with steady processing properties will play an important role in the semiconductor industry.

A chemically amplified photo-resist generally comprises three components: a matrix resin, an organic solvent, and a photoacid generator (PAG) for producing a chemical amplification action. After the chemically amplified photo-resist has been exposed to or illuminated with light, the PAG absorbs energy and undergoes a photolysis. Thus, free acid is generated, which results in an acid catalytic reaction such that the matrix resin in the exposure region undergoes a removal reaction of protecting groups or a cross-linking reaction between resin and cross linker, forming positive or negative latent images which are then subjected to development in a certain solvent to form exposure images. In addition, some chemically amplified photo-resists may employ a photobase generator (PBG) instead of a photoacid generator. An alkaline catalytic reaction takes place with the help of a photobase, which likewise results in that the matrix resin undergoes a removal reaction of protecting groups or a cross-linking reaction between resin and cross linker, forming a positive or negative latent image.

However, the contrast of the latent image will be degraded due to following factors: One factor is photoacid diffusion. The photoacid generated by illumination with a light in a first wavelength band will gradually diffuses from a position of high mass concentration to a position of low mass concentration through a free movement of molecules. In this way, the mass concentration distribution of the photoacid will depart from the optical image, thereby degrading the contrast of the latent image of the photoacid.

The other factor is photo diffraction. Theoretically, an optical image formed by means of a mask should be a simple binary image, that is, in the optical image, the light intensity of a portion of the image where the light is shielded by the mask is zero, while the light intensity of the other portion of the image where the light transmits through the mask is a constant. However, with the continuous shrinkage of the critical dimensions for a certain semiconductor process, light diffraction effect becomes more and more evident, such that the portion of the optical image that should have a light intensity of zero also has a certain light intensity. As a result, the contrast of the latent image of the photoacid is further degraded.

In the prior art, a photoacid diffusion length or depth is restricted to enhance the contrast of a latent image. However, this restriction is disadvantageous since it will make the removal reaction or the cross-linking reaction less efficient. Besides, the prior art also fails to overcome the degradation of the contrast of the latent image caused by the diffraction effect.

BRIEF SUMMARY OF THE INVENTION

The inventor of the present invention has found through experimentation that the prior art has a number of problems, and thus proposes a new technical solution to address at least one of the problems.

An embodiment of the present invention is to provide a photo-resist.

Another embodiment of the present invention is to provide a method for performing photolithography using this photo-resist.

According to one embodiment of the present invention, a photo-resist includes a matrix resin; a first component for producing chemical amplification action, wherein the first component is capable of generating a first chemical substance under illumination of a light in a first wavelength band, and the first chemical substance is capable of reacting with the matrix resin to form a latent image; and a second component that is capable of generating a second chemical substance under illumination of a light in a second wavelength band, wherein the second chemical substance is capable of reacting with the first chemical substance, thereby reducing a mass concentration of the first chemical substance in the photo-resist.

In an embodiment, the first component is a photoacid generator and the first chemical substance is a photoacid substance. The second component is a photobase generator and the second chemical substance is a photobase substance. In an exemplary embodiment, the photoacid generator can be (4-tert-butylphenyl) diphenylsulphonium triflate or triphenylsulphonium triflate, and the photobase generator can be quaternary ammonium salts.

In an embodiment, the photoacid generator can have a mass concentration ranging from 1% to 30%, and said photobase generator can have a mass concentration ranging from 0.1% to 20%, for example.

In an embodiment, said matrix resin is polyhydroxystyrene or polyacrylates.

In an embodiment, the first wavelength band may range from 170-220 nm, and the second wavelength band may range from 250 to 700 nm.

According to another embodiment of the present invention, a method for performing photolithography using the photo-resist of the present invention is disclosed. The method includes providing a substrate having a surface coated with the above described photo-resist, selectively illuminating a region of a surface of the photo-resist using the light in the first wavelength band, and uniformly illuminating the entire surface of the photo-resist using the light in the second wavelength band. The method also includes performing a development process for the photo-resist, thereby forming a desired photo-resist pattern.

In an embodiment, the light in the first wavelength band has an exposure dose from 0.1 to 100 mJ/cm².

In an embodiment, the light in the second wavelength band has an exposure dose from 0.1 to 100 mJ/cm².

In an embodiment, the step of illuminating using the light in the first wavelength band and the step of illuminating using the light in the second wavelength band are substantially performed at a same time.

In an embodiment, the first wavelength band may range from 170-220 nm, and the second wavelength band may range from 250 to 700 nm.

The present invention has the advantage that a portion of the photoacid is neutralized by the photobase, so that the contrast of the latent image can be enhanced.

Further features of the present invention and advantages thereof will become apparent from the following detailed description of exemplary embodiments according to the present invention with reference to the accompanying drawings.

### BRIEF DESCRIPTION OF THE DRAWINGS

The accompanying drawings, which are incorporated in and constitute a part of the specification, illustrate embodiments of the invention and, together with the description, serve to explain the principles of the invention.

The present invention can be more clearly understood based on the following detailed description and with the reference to the accompanying drawings, in which:

FIG. 1 is a flowchart illustrating a method for performing photolithography using the photo-resist according to an embodiment of the present invention.

FIG. 2 is a simplified diagram illustrating the exposure of the photo-resist using a light in a first wavelength band according to an embodiment of the present invention.

FIG. 3 shows a distribution curve of the mass concentration of the photoacid generated in the photo-resist according to an embodiment of the present invention.

FIG. 4 is a diagram illustrating the mass concentration distribution of the photoacid generated in the photo-resist according to an embodiment of the present invention.

FIG. 5 is a diagram illustrating illuminating the photo-resist using a light in a second wavelength band according to an embodiment of the present invention.

FIG. 6 is a diagram illustrating the mass concentration distribution of the photobase generated in the photo-resist according to an embodiment of the present invention.

FIG. 7 illustrates a distribution curve of the mass concentration of the photoacid in the photo-resist, after a neutralization reaction between the photoacid and the photobase, according to an embodiment of the present invention.

FIG. 8 is a diagram illustrating the mass concentration distribution of the photoacid in the photo-resist, after a neutralization reaction between the photoacid and the photobase, according to an embodiment of the present invention.

FIG. 9 is a diagram illustrating a development processing for the photo-resist according to an embodiment of the present invention.

FIG. 10 is a diagram illustrating a photo-resist pattern obtained by a photolithographic method according to an embodiment of the present invention.

### DETAILED DESCRIPTION OF THE INVENTION

Various exemplary embodiments of the present invention will now be described in detail with reference to the drawings. It should be noted that the relative arrangement of the components and steps, the numerical expressions, and numerical values set forth in these embodiments do not limit the scope of the present invention unless it is specifically stated otherwise.

It should also be understood that, for the convenience of description and for the sake of clarity, each component in the figures has not been necessarily drawn to scale.

The following description of at least one exemplary embodiment is merely illustrative in nature and is in no way intended to limit the invention, its application, or uses.

Techniques, methods and apparatus as known by one of ordinary skill in the relevant art may not be discussed in detail but are intended to be part of the specification where appropriate.

In all of the examples illustrated and discussed herein, any specific values should be interpreted to be illustrative only and non-limiting. Thus, other examples of the exemplary embodiments could have different values.

Notice that similar reference numerals and letters refer to similar items in the following figures, and thus, once an item is defined in one figure, it will not be further discussed in following figures.

The photo-resist according to an embodiment of the present invention includes a matrix resin; a first component for producing a chemical amplification action, wherein the first component is capable of generating a first chemical substance under illumination of a light in a first wavelength band, and the first chemical substance is capable of reacting with the matrix base to form a latent image. The photo-resist also includes a second component that is capable of generating a second chemical substance under illumination of a light of a second wavelength band. The second chemical substance is capable of reacting with the first chemical substance, so that a mass concentration of the first chemical substance in the photo-resist can be reduced.

According to another embodiment of the present invention, a photo-resist may include a photoacid generator (PAG), a photobase generator (PBG), a matrix resin and an organic solvent. In an example embodiment, polyhydroxystyrene or polyacrylates can be used for the matrix resin. For the organic solvent, various solvents as commonly used in the art can be employed, the description thereof will not be described herein for the sake of brevity. In this exemplary photo-resist, the photoacid generator is sensitive to the light in a first wavelength band. When the light in a first wavelength band is used to illuminate the photo-resist, it will absorb the light energy and undergo photolysis to generate a photoacid. The resin in the photo-resist will undergo, for example, a removal reaction, under the action with the photoacid, thereby causing the resin in the exposure region to go through a removal reaction of the protecting groups. The photoacid generator can be, for example, (4-tert-butylphenyl) diphenylsulphonium triflate or triphenylsulphonium triflate, or the like. These photoacid generators can generally have a mass concentration ranging from 1% to 30% in the photo-resist.

The photobase generator in the above photo-resist is sensitive to the light in a second wavelength band. When illuminated by the light in the second wavelength band, the photoacid generator absorbs light energy and undergoes photolysis to generate a photobase. Moreover, the first wavelength band is substantially different from the second wavelength band. In an embodiment, the first and second wavelength bands do not overlap. For example, the first wavelength band may range from 170-220 nm, and the second wavelength band may range from 250-700 nm. This photobase generator can be, for example, various quaternary ammonium salts. According to the different mass concentration of the photoacid generator, the mass concentration of the photobase generator can be selected from a range of 0.1% to 20%.

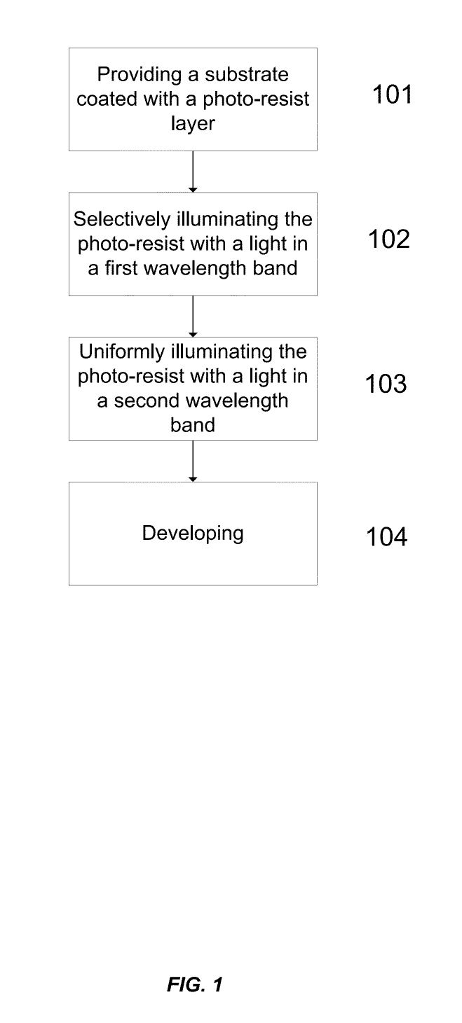

Below, in conjunction with FIGS. 1 to 10, a description about how to perform photolithography using the photo-resist mentioned in the above embodiments will be further provided.

As shown in FIG. 1, the method for performing photolithography using the photo-resist mentioned in the above embodiment may comprise the following steps:

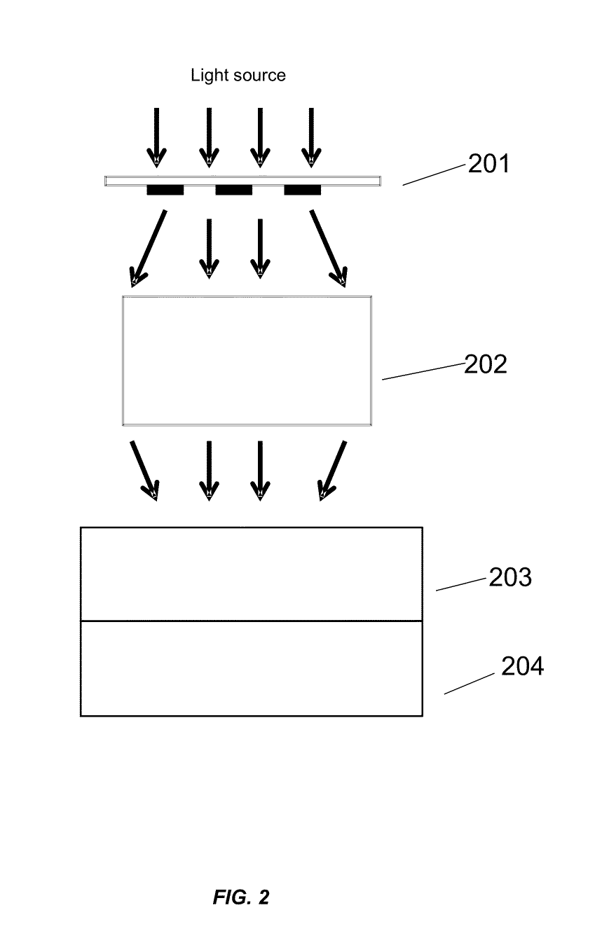

(1) Providing a substrate having a surface coated with a photo-resist (step 101). For example, as shown in FIG. 2, a layer of photo-resist 203 is uniformly coated over the surface of substrate 204.

(2) Selectively illuminating a region of a surface of the photo-resist using a light in a first wavelength band (step 202).

(3) Uniformly illuminating the entire surface of the photo-resist using a light in a second wavelength band (step 103).

(4) Performing development process for the photo-resist, thereby forming the desired photo-resist pattern (step 104).

The above sequence of processes provides a method according to an embodiment of the present invention. Other alternatives can also be provided where processes are added, one or more processes are removed without departing from the scope of the claims herein.

As shown in FIG. 2, an optical pattern is formed by a light in a first wavelength band that is emitted from a light source and has passed through mask 201. Then, the optical pattern is projected onto the surface of photo-resist 203 by means of an exposure optical element 202.

The photoacid generator in the photo-resist undergoes photolysis due to the absorption of the light in the first wavelength band, thereby generating photoacid in the photo-resist. One of ordinary skill in the art should appreciate that the mass concentration of the generated photoacid is related to parameters such as the exposure dose of the light in the first wavelength band and the mass concentration of the photoacid generator. In this embodiment, the light in the first wavelength band has an exposure dose from 0.1 to 100 mJ/cm², for example. In this manner, the optical image is converted into a latent image of the photoacid.

In an ideal situation, the higher the contrast of the latent image of the photoacid, the better, because, in this way, the photo-resist pattern formed after development will have a relatively small edge roughness. However, due to photoacid diffusion as well as optical diffraction of mask 201, the contrast of the latent image will be degraded.

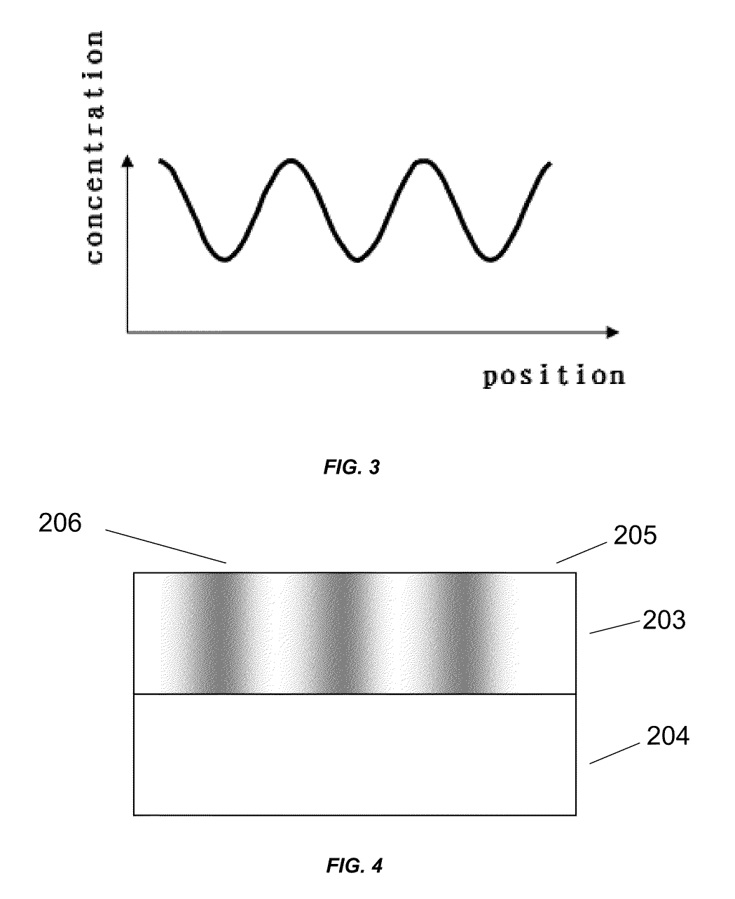

FIG. 3 shows a distribution curve of the mass concentration of the photoacid generated in the photo-resist. As shown in FIG. 3, the mass concentration of the photoacid is larger than zero at any position. Herein, one of ordinary skill in the art will appreciate that the mass concentration of the photoacid at any position refers to a ratio between the mass of the photoacid generated in an infinitesimal of the photo-resist and the mass of the infinitesimal of the photo-resist at this position. As shown, the minimum value of the mass concentration of the photoacid is non-zero.

FIG. 4 illustrates a distribution of the photoacid in the photo-resist. As shown in FIG. 4, dark regions 206 indicate positions where a mass concentration of the photoacid is low while white regions 205 indicate positions where a mass concentration of the photoacid is high. Corresponding to the distribution curve of the mass concentration of the photoacid in FIG. 3, as the mass concentration of the photoacid gradually decreases from a maximum value to a minimum (non-zero) value, white region 205 gradually transits to dark region 206 in photo-resist 203. Due to the influence of photoacid diffusion and diffraction of the mask as mentioned above, the transitional region between dark region 206 and white region 205 is relatively indistinct, that is, the contrast of the latent image of the photoacid is relatively low.

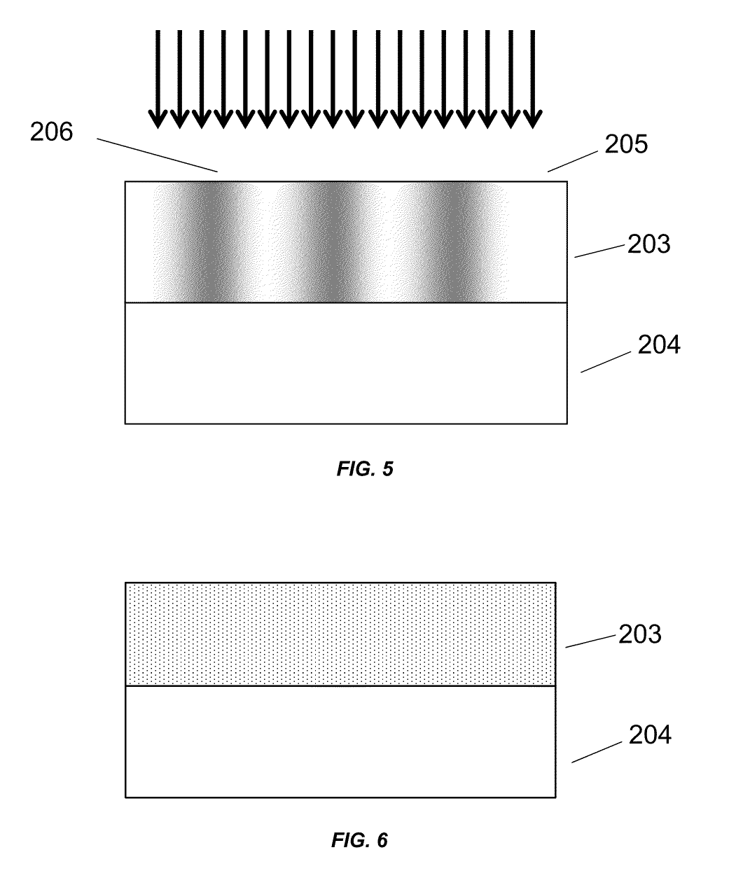

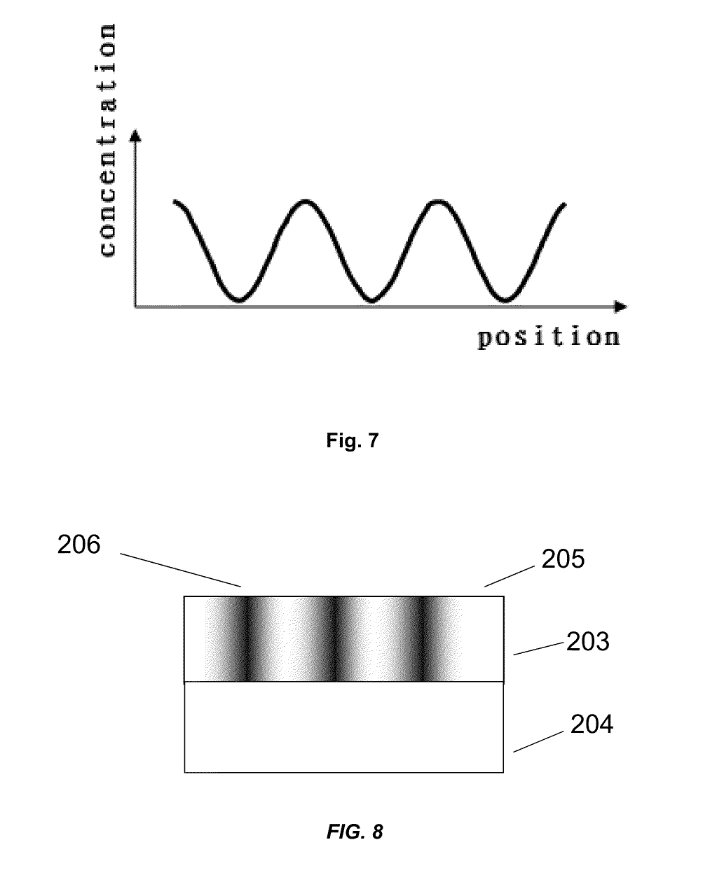

At process step 103, the entire surface of the photo-resist is illuminated using a light in a second wavelength band. As shown in FIG. 5, a light in a second wavelength band uniformly illuminates the surface of the photo-resist. Since the photobase generator in photo-resist 203 is sensitive to the light in the second wavelength band, a photobase of uniform mass concentration will be generated in photo-resist 203, as shown in FIG. 6. The mass concentration of the photobase can be controlled by controlling parameters such as the exposure dose of the light in the second wavelength band, the mass concentration of the photobase generator, etc. In this embodiment, the light in the second wavelength band can have an exposure dose from, for example, 0.1 to 100 mJ/cm². Moreover, when the mass concentration of the photobase is less than the minimum value of the mass concentration of the photoacid, for example, the photobase in the photo-resist will neutralize a portion of the photoacid, such that the mass concentration of the photoacid decreases throughout the photo-resist. As shown in FIG. 7, after the neutralization reaction, the minimum value of the mass concentration of the photoacid is close to zero.

FIG. 8 further shows the latent image of the photoacid after the neutralization reaction. In FIG. 8, dark region 206 becomes darker as compared with that of FIG. 4, which indicates that the photoacid in the dark region 206 has been substantially eliminated by the neutralization reaction. Thus, the contrast of the latent image of the photoacid is enhanced.

Moreover, the step of illuminating with a light in a first wavelength band and the step of illuminating with a light in a second wavelength band can be performed with a certain interval there between. With the hint of the present invention, one of ordinary skill in the art can reasonably select such an interval. In this embodiment, a more preferred solution is that the two steps are performed at a same time, that is, the photo-resist is simultaneously illuminated with the light in a first wavelength band and the light in a second wavelength band. This solution has the advantage that the photolithographic processing can be performed at high speed and the photolithographic efficiency is enhanced.

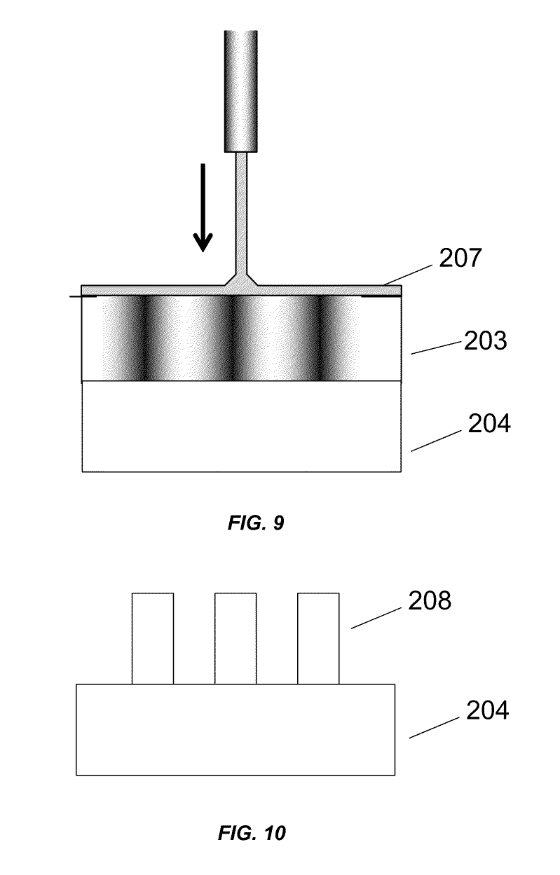

At process step 104, a development process is performed for the photo-resist, thereby forming the desired photo-resist pattern. As shown in FIG. 9, a development process is performed for photo-resist 203 using a developer 207. Regarding the exemplary positive photo-resist 203 in this embodiment, the white region (an region where the photoacid is generated) is removed while the dark region (an region without photoacid) is maintained, thereby forming a photo-resist pattern 208 as shown in FIG. 10.

In the above embodiment, since the photoacid generator and the photobase generator are sensitive to different wavelength bands, it is possible to illuminate the photo-resist respectively using the light in different wavelength bands during the exposure process, such that the mass concentration of the photoacid and the mass concentration of the photobase in the photo-resist can be individually controlled and adjusted. Then, by means of the neutralization reaction between the photoacid and the photobase, the contrast of the latent image of the photoacid can be enhanced, and thus the edge roughness of the finally formed photo-resist pattern can be improved. The method of the present invention can not only overcome the adverse influence on the contrast of the latent image of the photoacid that is caused by the photoacid diffusion, but also further overcome the degradation of the contrast of the latent image of the photoacid due to diffraction of the mask.

Of course, the photo-resist illustrated above is a positive photo-resist. One of ordinary skill in the art will appreciate that a negative photo-resist also can be obtained in a similar manner.

So far, the photo-resist according to the present invention as well as the method for performing photolithography using this photo-resist has been described above in detail. In order to not obscure the concept of the present invention, some details as known in the art are not described. One of ordinary skill in the art will know how to implement the technical solution disclosed herein based on the above description.

Although some specific embodiments of the present invention have been demonstrated in detail with examples, it should be understood by one of ordinary skill in the art that the above examples are only intended to be illustrative but not to limit the scope of the present invention. It should be understood by a person skilled in the art that the above embodiments can be modified without departing from the scope and spirit of the present invention. The scope of the present invention is defined by the attached claims.

What is claimed is:

1. A photo-resist, comprising:
a matrix resin;
a first component for producing a chemical amplification action, wherein the first component is capable of generating a first chemical substance under illumination of a light in a first wavelength band, and the first chemical substance is capable of reacting with the matrix resin to form a latent image; and
a second component that is capable of generating a second chemical substance under illumination of a light in a second wavelength band, wherein the second chemical substance is capable of reacting with the first chemical substance, thereby reducing a mass concentration of the first chemical substance in the photo-resist.

2. The photo-resist of claim 1, characterized in that,
said first component is a photoacid generator and said first chemical substance is a photoacid; and
said second component is a photobase generator and said second chemical substance is a photobase.

3. The photo-resist of claim 2, characterized in that, said photoacid generator is (4-tert-butylphenyl) diphenylsulphonium triflate or triphenylsulphonium triflate.

4. The photo-resist of claim 2, characterized in that, said photobase generator is a quaternary ammonium salt.

5. The photo-resist of claim 2, characterized in that, said photoacid generator has a mass concentration ranging from 1% to 30%.

6. The photo-resist of claim 2, characterized in that, said photobase generator has a mass concentration ranging from 0.1% to 20%.

7. The photo-resist of claim 1, characterized in that, said matrix resin is polyhydroxystyrene or polyacrylates.

8. The photo-resist of claim 1, characterized in that, the first wavelength band ranges from 170 to 220 nm, and the second wavelength band ranges from 250 to 700 nm.

9. A method for performing photolithography using the photo-resist claimed in claim 1, comprising the following steps:
providing a substrate having a surface coated with said photo-resist;
selectively illuminating a region of a surface of said photo-resist using the light in the first wavelength band;
uniformly illuminating the entire surface of said photo-resist using the light in the second wavelength band;
performing development process for said photo-resist, thereby forming a desired photo-resist pattern.

10. The method of claim 9, characterized in that, the light in the first wavelength band has an exposure dose from 0.1 to 100 mJ/cm².

11. The method of claim 9, characterized in that, the light in the second wavelength band has an exposure dose from 0.1 to 100 mJ/cm².

12. The method of claim 9, characterized in that, the step of illuminating using the light in the first wavelength band and the step of illuminating using the light in the second wavelength band are substantially performed at a same time.

13. The method of claim 9, wherein the photo-resist is characterized in that,
said first component is a photoacid generator and said first chemical substance is a photoacid; and
said second component is a photobase generator and said second chemical substance is a photobase.

14. The method of claim 13, wherein the photo-resist is characterized in that, said photoacid generator is (4-tert-butylphenyl) diphenylsulphonium triflate or triphenylsulphonium triflate.

15. The method of claim 13, wherein the photo-resist is characterized in that, said photobase generator is a quaternary ammonium salt.

16. The method of claim 13, wherein the photo-resist is characterized in that, said photoacid generator has a mass concentration ranging from 1% to 30%.

17. The method of claim 13, wherein the photo-resist is characterized in that, said photobase generator has a mass concentration ranging from 0.1% to 20%.

18. The method of claim 13, wherein the photo-resist is characterized in that, said matrix resin is polyhydroxystyrene or polyacrylates.

19. The method of claim 13, wherein the photo-resist is characterized in that, the first wavelength band ranges from 170-220 nm, and the second wavelength band ranges from 250 to 700 nm.
